(19) United States
(12) Patent Application Publication
(10) Pub. No.: US 2026/0247816 A1
(43) Pub. Date: Aug. 20, 2026

(54) DISPLAY DEVICE AND ELECTRONIC DEVICE

(71) Applicant: Samsung Display Co., LTD., Yongin-si (KR)

(72) Inventors: KANGMOON JO, Yongin-si (KR); JIAN SHIN, Yongin-si (KR); SI HYUN AHN, Yongin-si (KR)

(21) Appl. No.: 19/430,799

(22) Filed: Dec. 23, 2025

(30) Foreign Application Priority Data
Feb. 18, 2025 (KR) 10-2025-0020992

(51) Int. Cl. H10K 59/131

(52) U.S. Cl. CPC H10K 59/131

(57) ABSTRACT

A display device according to the inventive concept includes a display panel including a pad area, a plurality of pads disposed in the pad area, aligned in a first direction, and each extending in a diagonal direction inclined at a first angle with respect to a second direction crossing the first direction, and an inspection pattern extending in the diagonal direction and corresponding to at least a portion of the plurality of pads.

This application claims priority to Korean Patent Application No. 10-2025-0020992, filed on Feb. 18, 2025, and all the benefits accruing therefrom under 35 U.S.C. §119, the content of which in its entirety is herein incorporated by reference.

### BACKGROUND

### Field

The present disclosure herein relates to a display device and an electronic device, and more particularly, to a display device and an electronic device each with improved reliability.

### Description of the Related Art

Display devices such as televisions, monitors, smartphones, and tablet computers, which provide images for users, include display panels which display the images. Various display panels such as liquid crystal display panels, organic light emitting display panels, electro wetting display panels, and electrophoretic display panels, are being developed as the display panels.

A display device includes a display area that is activated in response to an electrical signal. The display device may detect an input applied from the outside through a display area, and the display device also display various images to provide information for a user.

The display device includes a display panel and a circuit board. The display panel may be connected to a main board through the circuit board. A driving chip may be mounted on the display panel. The driving chip may be electrically connected to the display panel through pads disposed in a non-display area of the display panel.

### SUMMARY

The present disclosure provides a display device and an electronic device each capable of inspecting whether or not pads are arranged.

An embodiment of the inventive concept provides a display device including a display panel including a pad area, a plurality of pads disposed in the pad area, aligned in a first direction, and each extending in a diagonal direction inclined at a first angle with respect to a second direction crossing the first direction, and an inspection pattern extending in the diagonal direction and corresponding to at least a portion of the plurality of pads.

In an embodiment of the inventive concept, a display device includes a display panel including a pad area, a plurality of pads disposed in the pad area, aligned in a first direction, and each extending in a diagonal direction inclined at a first angle with respect to a second direction crossing the first direction, a sub-pattern electrically connected to the plurality of pads and extending in the diagonal direction to correspond to the plurality of pads, and an insulating layer disposed on the plurality of pads and the sub-pattern. The plurality of pads may be exposed by an opening portion defined in the insulating layer.

In an embodiment of the inventive concept, an electronic device includes a display panel including a pad area, a plurality of pads disposed in the pad area, aligned in a first direction, and each extending in a diagonal direction inclined at a first angle with respect to a second direction crossing the first direction, an inspection pattern extending in the diagonal direction and corresponding to at least a portion of the plurality of pads, and a printed circuit board including a plurality of connection pads and electrically connected to the display panel through the plurality of connection pads.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1A is a block diagram of an electronic device according to an embodiment of the inventive concept;

FIGS. 1B to 1D are each a perspective view of an electronic device according to an embodiment of the inventive concept;

FIG. 2 is a perspective view of an electronic device according to an embodiment of the inventive concept;

FIG. 3 is an exploded perspective view of an electronic device according to an embodiment of the inventive concept;

FIGS. 4A and 4B are plan views of a display device according to an embodiment of the inventive concept;

FIG. 5 is a cross-sectional view of a display module according to an embodiment of the inventive concept;

FIG. 6 is an enlarged view of area AA' illustrated in FIG. 4A;

FIG. 7 is a cross-sectional view taken along line I-I' illustrated in FIG. 6;

FIG. 8 is a cross-sectional view of a portion of an electronic device according to an embodiment of the inventive concept;

FIG. 9 is a view illustrating a portion of a display panel DPa according to an embodiment of the inventive concept; and

FIG. 10 is a view illustrating a portion of a display panel DP according to an embodiment of the inventive concept.

### DETAILED DESCRIPTION

In this specification, it will be understood that when an element (or a region, a layer, a portion, or the like) is referred to as being "on", "connected to" or "coupled to" another element, it may be directly disposed on, connected to, or coupled to the other element, or other elements may be disposed therebetween.

Like reference symbols refer to like elements throughout. In the drawings, the thickness, ratio, and size of the elements are exaggerated for effectively describing the technical contents. As used herein, the term "and/or" includes any and all combinations of one or more of the associated listed elements.

It will be understood that, although the terms "first", "second", and the like may be used herein to describe various elements, the elements are not to be limited by these terms. These terms are used to distinguish one element, component, region, layer or section from another element, component, region, layer or section. For instance, a first element, component, region, layer or section discussed below could be termed a second element, component, region, layer or section without departing from the scope of the inventive concept. Similarly, a second element, component, region, layer or section could be termed a first element, component, region, layer or section. In this specification, the singular expressions "a", "an" and "the" are intended to include the plural forms as well, unless the context clearly indicates otherwise.

In some aspects, the terms "below", "on the lower side", "above", "on the upper side", or the like are used to describe the relationships between the elements illustrated in the drawings. These terms are relative concepts and are described on the basis of the directions indicated in the drawings.

It will be further understood that the terms "comprises, includes, has" and/or "comprising, including, having", when used in this specification, specify the presence of stated features, numbers, steps, operations, elements, components or combinations thereof, but do not preclude the possibility of the presence or addition of one or more other features, numbers, steps, operations, elements, components, and/or combinations thereof.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ± 30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept will be described with reference to the accompanying drawings.

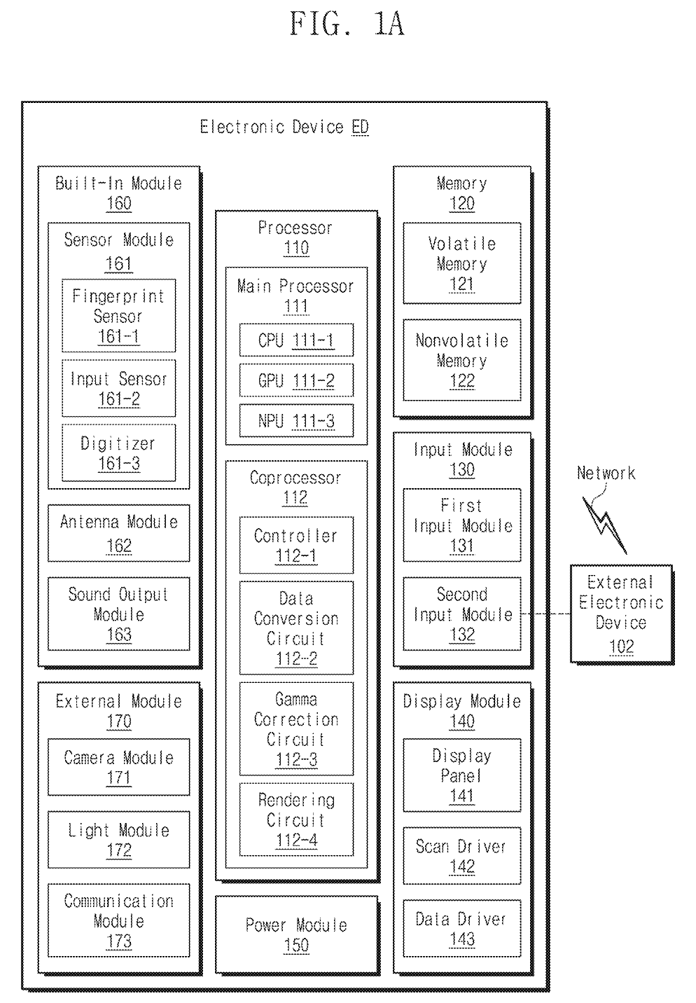

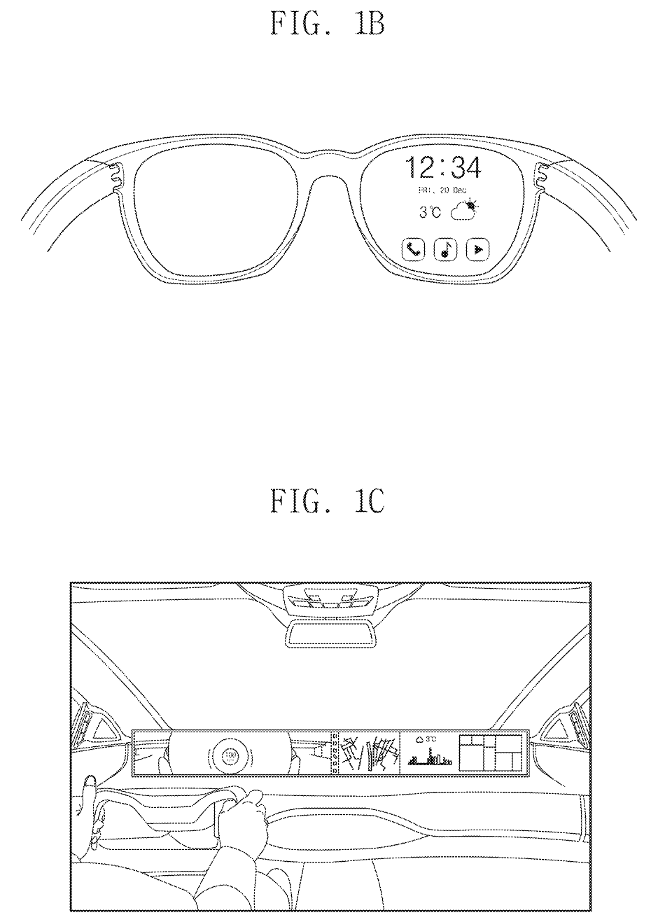

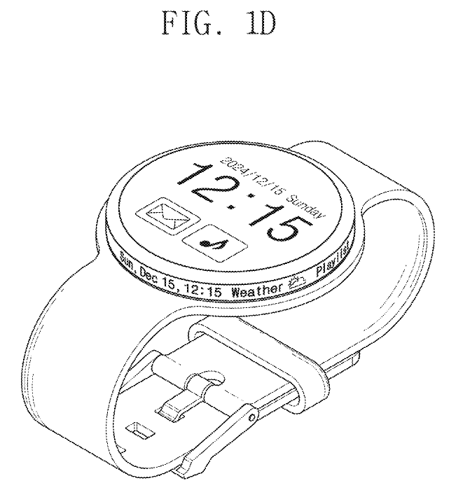

FIG. 1A is a block diagram of an electronic device according to an embodiment of the inventive concept. FIGS. 1B to 1D are each a perspective view of an electronic device according to an embodiment of the inventive concept.

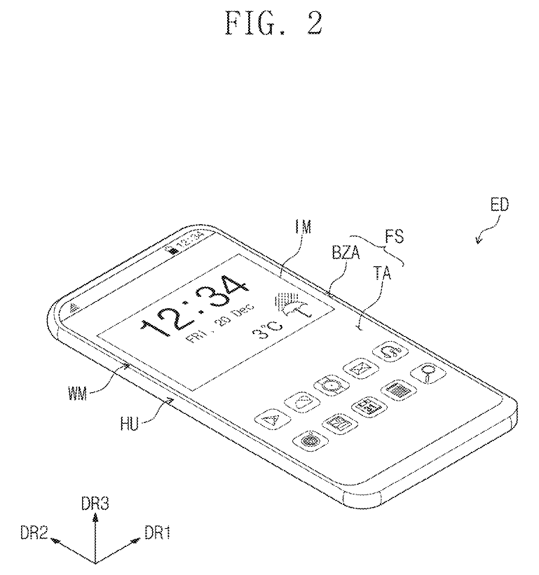

An electronic device ED according to an embodiment of the inventive concept includes a display device DD. The electronic device ED according to an embodiment of the inventive concept may be a mobile phone as illustrated in FIG. 2, but is not limited thereto.

As illustrated in FIG. 1A, the electronic device ED outputs various information through a display module 140 in an operating system. In an example in which a processor 110 executes an application stored in a memory 120, the display module 140 provides application information for a user through a display panel 141.

The processor 110 obtains an external input through an input module 130 or a sensor module 161, and executes an application corresponding to the external input. In an example in which the user selects a camera icon displayed on the display panel 141, the processor 110 obtains a user input through an input sensor 161-2 and activates a camera module 171. The processor 110 transmits, to the display module 140, image data corresponding to a photographing image obtained through the camera module 171. The display module 140 may display an image corresponding to the photographing image through the display panel 141.

As another example, when individual information authentication is performed in the display module 140, a fingerprint sensor 161-1 obtains input fingerprint information as input data. The processor 110 compares the input data obtained through the fingerprint sensor 161-1 with authentication data stored in the memory 120, and executes an application according to a result of the comparison. The display module 140 may display, through the display panel 141, information executed according to a logic of the application.

As another example, when a music streaming icon displayed on the display module 140 is selected, the processor 110 obtains a user input through the input sensor 161-2 and activates a music streaming application stored in the memory 120. In an example in which a music play command is input to the music streaming application, the processor 110 activates a sound output module 163 and provides the user with sound information corresponding to the music play command.

In the above, the operations of the electronic device ED are described in brief. Hereinafter, components of the electronic device ED will be described in detail. Among the components of the electronic device ED to be described later, some components may be integrally provided as one component, and one component may be provided as divided into two or more components.

Referring to FIG. 1A, the electronic device ED may communicate with an external electronic device 102 over a network (e.g., a short-range wireless communication network or a long-range wireless communication network). According to an embodiment, the electronic device ED may include the processor 110, the memory 120, the input module 130, the display module 140, a power module 150, a built-in module 160, and an external module 170. According to an embodiment, in the electronic device ED, at least one of the foregoing components may be omitted, or one or more other components may be added. According to an embodiment, some (e.g., the sensor module 161, an antenna module 162, or the sound output module 163) of the foregoing components may be integrated into another component (e.g., the display module 140).

The processor 110 may execute software to control at least one other component (e.g., a hardware or software component) of the electronic device ED connected to the processor 110, and may perform various data processing or computation. According to an embodiment, as at least a part of the data processing or computation, the processor 110 may store a command or data received from other component (e.g., the input module 130, the sensor module 161, or a communication module 173) in a volatile memory 121, process the command or data stored in the volatile memory 121, and store the resulting data in a nonvolatile memory 122.

The processor 110 may include a main processor 111 and a coprocessor 112. The main processor 111 may include at least one of a central processing unit (CPU) 111-1 or an application processor (AP). The main processor 111 may further include at least one of a graphic processing unit (GPU) 111-2, a communication processor (CP), or an image signal processor (ISP). The main processor 111 may further include a neural processing unit (NPU) 111-3. The neural processing unit may be a processor specialized for processing of an artificial intelligence model, and the artificial intelligence model may be created through machine learning. The artificial intelligence model may include a plurality of artificial neural network layers. The artificial neural network may include one of deep neural network (DNN), convolutional neural network (CNN), recurrent neural network (RNN), restricted boltzmann machine (RBM), deep belief network (DBN), bidirectional recurrent deep neural network (BRDNN), deep Q-networks, or a combination of two or more of the foregoing networks, but is not limited to the foregoing examples. Additionally or alternatively, the artificial intelligence model may include a software structure in addition to a hardware structure. At least two of the foregoing processing units and processors may be implemented as one integrated component (e.g., a single chip), or the foregoing processing units and processors may be implemented as independent components (e.g., a plurality of chips).

The coprocessor 112 may include a controller 112-1. The controller 112-1 may include an interface conversion circuit and a timing control circuit. The controller 112-1 receives an image signal from the main processor 111 and outputs image data obtained by converting a data format of the image signal such that the image signal is suitable for the specification of an interface with the display module 140. The controller 112-1 may output various control signals supportive of driving the display module 140.

The coprocessor 112 may further include a data conversion circuit 112-2, a gamma correction circuit 112-3, a rendering circuit 112-4, or the like. The data conversion circuit 112-2 may receive image data from the controller 112-1, and compensate for the image data such that an image is displayed with a desired luminance according to a characteristic of the electronic device ED or user settings, or convert the image data to reduce power consumption or compensate for image-sticking. The gamma correction circuit 112-3 may convert image data, a gamma reference voltage, or the like such that an image displayed on the electronic device ED1 has a desired gamma characteristic. The rendering circuit 112-4 may receive the image data from the controller 112-1, and render the image data in consideration of a pixel arrangement of the display panel 141 applied to the electronic device ED, or the like. At least one of the data conversion circuit 112-2, the gamma correction circuit 112-3, or the rendering circuit 112-4 may be integrated into another component (e.g., the main processor 111 or the controller 112-1). At least one of the data conversion circuit 112-2, the gamma correction circuit 112-3, or the rendering circuit 112-4 may be integrated into a data driver 143 to be described later.

The memory 120 may store various data used by at least one component (e.g., the processor 110 or the sensor module 161) of the electronic device ED, and input data or output data for relevant commands. The memory 120 may include at least one of the volatile memory 121 or the nonvolatile memory 122.

The input module 130 may receive a command or data to be used in a component (e.g., the processor 110, the sensor module 161, or the sound output module 163) of the electronic device ED from the outside of the electronic device ED (e.g., the user or the external electronic device 102).

The input module 130 may include a first input module 131 to which a command or data is input from the user, and a second input module 132 to which a command or data is input from the external electronic device 102. The first input module 131 may include a microphone, a mouse, a keyboard, a key (e.g., a button), or a pen (e.g., a passive pen or an active pen). The second input module 132 may support a designated protocol which may be connected to the external electronic device 102 in a wired or wireless manner. According to an embodiment, the second input module 132 may include a high definition multimedia interface (HDMI), a universal serial bus (USB) interface, a secure digital (SD) card interface, or an audio interface. The second input module 132 may include a connector which may be physically connected to the external electronic device 102, for example, an HDMI connector, a USB connector, an SD card connector, or an audio connector (e.g., a headphone connector).

The display module 140 visually provides information for the user. The display module 140 may include the display panel 141, a scan driver 142, and the data driver 143. The display module DM may further include a window, a chassis, or a bracket for protecting the display panel 141.

The display panel 141 may include a liquid crystal display panel, an organic light emitting display panel, or an inorganic light emitting display panel, and the type of the display panel 141 is not particularly limited. The display panel 141 may be a rigid type, or a flexible type capable of rolling or folding. The display module 140 may further include a supporter which supports the display panel 141, a bracket, a heat dissipation member, or the like.

The scan driver 142 may be mounted as a driving chip on the display panel 141. Alternatively, the scan driver 142 may be integrated into the display panel 141. For example, the scan driver 142 may include an amorphous silicon TFT gate driver circuit (ASG), a low temperature polycrystalline silicon (LTPS) TFT gate driver circuit, or an oxide semiconductor TFT gate driver circuit (OSG), internalized into the display panel 141. The scan driver 142 receives a control signal from the controller 112-1, and outputs scan signals to the display panel 141 in response to the control signal.

The display panel 141 may further include an emission driver. The emission driver outputs an emission control signal to the display panel 141 in response to the control signal received from the controller 112-1. The emission driver may be separated from the scan driver 142, or be integrated into the scan driver 142.

The data driver 143 receives the control signal from the controller 112-1, and converts image data into analog voltages (e.g., data voltages) in response to the control signal and then outputs the data voltages to the display panel 141.

The data driver 143 may be incorporated into other component (e.g., the controller 112-1). The functions of the interface conversion circuit and the timing control circuit of the controller 112-1 described herein may be incorporated into the data driver 143.

The display module 140 may further include the emission driver, a voltage generation circuit, and the like. The voltage generating circuit may output various voltages supportive of driving the display panel 141.

The power module 150 supplies power to the components of the electronic device ED. The power module 150 may include a battery which charges a power voltage. The battery may include a non-rechargeable primary battery, a rechargeable secondary battery, or a fuel battery. The power module 150 may include a power management integrated circuit (PMIC). The PMIC supplies optimized power to each of the modules described herein and modules to be described later. The power module 150 may include a wireless power transmission/reception member electrically connected to the battery. The wireless power transmission/reception member may include a plurality of antenna radiators in the form of coils.

The electronic device ED may further include the built-in module 160 and the external module 170. The built-in module 160 may include the sensor module 161, the antenna module 162, and the sound output module 163. The external module 170 may include the camera module 171, a light module 172, and the communication module 173.

The sensor module 161 may detect an input by the user's body or an input by a pen of the first input module 131, and generate an electrical signal or data value corresponding to the input. The sensor module 161 may include at least one of the fingerprint sensor 161-1, the input sensor 161-2, or a digitizer 161-3.

The fingerprint sensor 161-1 may generate a data value corresponding to the user's fingerprint. The fingerprint sensor 161-1 may include one of an optical or capacitance fingerprint sensor.

The input sensor 161-2 may generate a data value corresponding to coordinate information of an input by the user's body or an input by a pen. The input sensor 161-2 generates a capacitance change due to the input as a data value. The input sensor 161-2 may detect an input by the passive pen or transmit/receive data to/from the active pen.

The input sensor 161-2 may measure a bio-signal such as blood pressure, moisture, or body fat. In an example in which the user touches a sensor layer or a sensing panel with part of the body and does not move for a certain period of time, on the basis of a change in electric field caused by the part of the body, the input sensor 161-2 may detect a bio-signal and output information desired by the user to the display module 140.

The digitizer 161-3 may generate a data value corresponding to coordinate information of an input by the pen. The digitizer 161-3 generates an electromagnetic change by the input as a data value. The digitizer 161-3 may detect an input by the passive pen or transmit/receive data to/from the active pen.

At least one of the fingerprint sensor 161-1, the input sensor 161-2, or the digitizer 161-3 may be provided as a sensor layer formed on the display panel 141 through a continuous process. The fingerprint sensor 161-1, the input sensor 161-2, and the digitizer 161-3 may be disposed above the display panel 141, and one of the fingerprint sensor 161-1, the input sensor 161-2, and the digitizer 161-3, for example, the digitizer 161-3, may be disposed below the display panel 141.

At least two of the fingerprint sensor 161-1, the input sensor 161-2, and the digitizer 161-3 may be integrated into one sensing panel through the same process. In an example in which the at least two are integrated into the one sensing panel, the sensing panel may be disposed between the display panel 141 and a window disposed above the display panel 141. According to an embodiment, the sensing panel may be disposed on the window, and a position of the sensing panel is not particularly limited.

At least one of the fingerprint sensor 161-1, the input sensor 161-2, or the digitizer 161-3 may be built in the display panel 141. That is, at least one of the fingerprint sensor 161-1, the input sensor 161-2, or the digitizer 161-3 may be simultaneously formed through a process of forming elements (e.g., light emitting elements, transistors, or the like) included in the display panel 141.

In some aspects, the sensor module 161 may generate an electrical signal or a data value corresponding to an internal or external state of the electronic device ED. The sensor module 161 may further include, for example, a gesture sensor, a gyro sensor, a barometric pressure sensor, a magnetic sensor, an acceleration sensor, a grip sensor, a proximity sensor, a color sensor, an IR (infrared) sensor, a biosensor, a temperature sensor, a humidity sensor, or an illuminance sensor.

The antenna module 162 may include at least one antenna for transmitting a signal or power to the outside or receiving a signal or power from the outside. According to an embodiment, the communication module 173 may transmit a signal to an external electronic device or receive a signal from the external electronic device through an antenna suitable for a communication method. An antenna pattern of the antenna module 162 may be integrated into one component (e.g., the display panel 141) of the display module 140, the input sensor 161-2, or the like.

The sound output module 163 may be a device for outputting a sound signal to the outside of the electronic device ED, and include, for example, a speaker used for general purposes such as multimedia playback or recording playback, and a receiver used exclusively for receiving calls. According to an embodiment, the receiver may be formed integrally with or separately from the speaker. A sound output pattern of the sound output module 163 may be integrated into the display module 140.

The camera module 171 may photograph still images and moving images. According to an embodiment, the camera module 171 may include one or more lenses, image sensors, or image signal processors. The camera module 171 may further include an infrared camera capable of measuring the presence/absence of a user, the user's position, the user's gaze, or the like.

The light module 172 may provide light. The light module 172 may include a light emitting diode or a xenon lamp. The light module 172 may operate in conjunction with the camera module 171 or operate independently.

The communication module 173 may establish a wired or wireless communication channel between the electronic device ED and the external electronic device 102, and support communication through the established communication channel. The communication module 173 may include one or all of a wireless communication module such as a cellular communication module, a short-range wireless communication module, or a global navigation satellite system (GNSS) communication module, and a wired communication module such as a local area network (LAN) communication module or a power line communication module. The communication module 173 may communicate with the external electronic device 102 through a short-range communication network such as Bluetooth, WiFi direct, or infrared data association (IrDA), or a long-range communication network such as cellular network, Internet, or computer network (e.g., LAN or WAN). The foregoing various types of communication modules 173 may be implemented as a single chip, or implemented as separate chips, respectively.

The input module 130, the sensor module 161, the camera module 171, and the like may be utilized to control the operation of the display module 140 in conjunction with the processor 110.

The processor 110 outputs a command or data to the display module 140, the sound output module 163, the camera module 171, or the light module 172 on the basis of input data received from the input module 130. For example, the processor 110 may generate image data in response to the input data inputted through a mouse, an active pen, or the like, and output the image data to the display module 140, or may generate command data in response to the input data and output the command data to the camera module 171 or the light module 172. In an example in which the input data is not received from the input module 130 for a certain period of time, the processor 110 may convert an operation mode of the electronic device ED into a low power mode or a sleep mode, thereby reducing power consumed by the electronic device ED.

The processor 110 outputs a command or data to the display module 140, the sound output module 163, the camera module 171, or the light module 172 on the basis of sensing data received from the sensor module 161. For example, the processor 110 may compare authentication data inputted by the fingerprint sensor 161-1 with authentication data stored in the memory 120 and then execute an application according to a result of the comparison. The processor 110 may execute a command or output corresponding image data to the display module 140 on the basis sensing data detected by the input sensor 161-2 or the digitizer 161-3. In an example in which the sensor module 161 includes a temperature sensor, the processor 110 may receive temperature data for measured temperatures from the sensor module 161, and further perform a luminance correction, or the like on the image data on the basis of the temperature data.

The processor 110 may receive measurement data about the presence/absence of a user, the position of the user, the user's gaze, or the like from the camera module 171. The processor 110 may further perform the luminance correction or the like on the image data on the basis of the measurement data. For example, the processor 110 having determined the presence/absence of a user through an input from the camera module 171 may output, to the display module 140, image data in which the luminance is corrected through the data conversion circuit 112-2 or the gamma correction circuit 112-3.

Some of the foregoing components may be connected to each other through a method for communication between peripheral devices, for example, bus, general purpose input/output (GPIO), serial peripheral interface (SPI), mobile industry processor interface (MIPI), or ultra path interconnect (UPI) link, and exchange signals (e.g., commands or data). The processor 110 may communicate with the display module 140 through an appointed interface. For example, one of the foregoing communication methods may be used, and the communication method is not limited to the foregoing communication methods.

The electronic devices ED according to various embodiments described herein may be various types of devices. The electronic device ED may include, for example, at least one of a portable communication device (e.g., a smartphone), a tablet device, a portable multimedia device, a wearable device, or a home appliance. The electronic device ED according to an embodiment herein is not limited to the foregoing devices. AR glasses illustrated in FIG. 1B, various types of in-vehicle information devices illustrated in FIG. 1C, and a smart watch illustrated in FIG. 1D may be implemented as the electronic device ED according to an embodiment of the inventive concept.

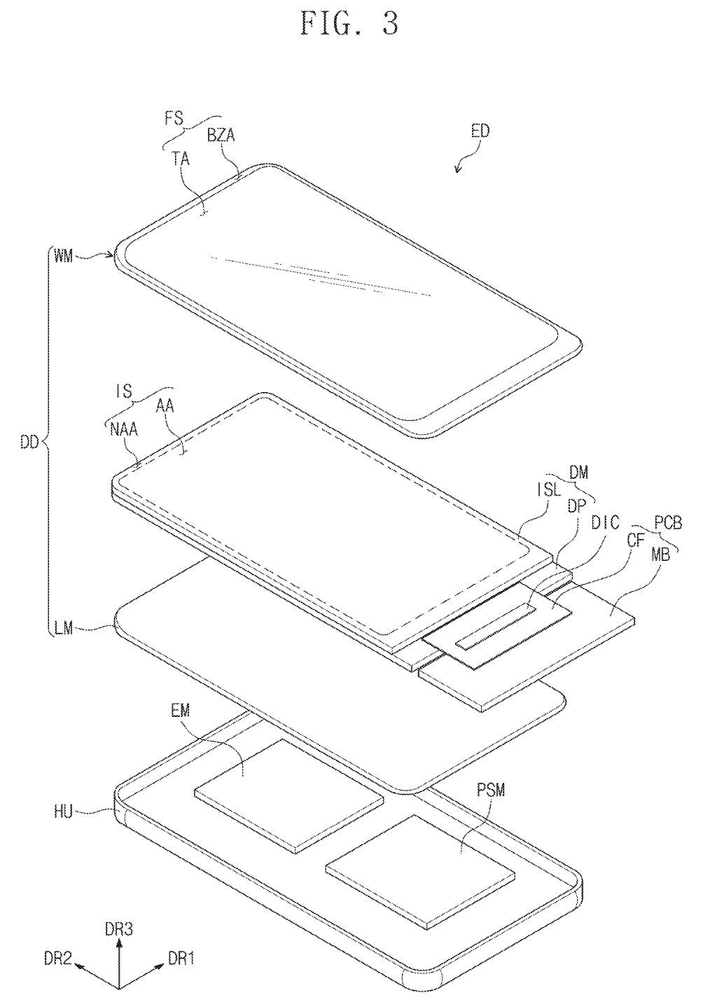

FIG. 2 is a perspective view of an electronic device according to an embodiment of the inventive concept. FIG. 3 is an exploded perspective view of an electronic device according to an embodiment of the inventive concept.

An electronic device ED may be a device that is activated in response to an electrical signal. The electronic device ED may include various embodiments. For example, the electronic device ED may be applied to an electronic device such as mobile phone, smart watch, tablet computer, notebook computer, computer, or smart television. A display device according to the inventive concept is not limited to the foregoing examples, and may be employed as another electronic device unless departing from the inventive concept. In this embodiment, a mobile phone is illustrated as an example of the electronic device ED.

The electronic device ED may display an image IM toward a third direction DR3 on a display surface FS parallel to each of a first direction DR1 and a second direction DR2. The display surface FS on which the image IM is displayed may correspond to a front surface of a display device DD. The image IM may include not only a dynamic image but also a still image. In FIG. 2, a clock window and icons are illustrated as an example of the image IM.

In this embodiment, a front surface (or top surface) and a rear surface (or bottom surface) of each member are defined on the basis of a direction in which the image IM is displayed. The front surface and the rear surface may oppose each other in the third direction DR3, and a normal direction to each of the front surface and the rear surface may be parallel to the third direction DR3. A separation distance between the front surface and the rear surface in the third direction DR3 may correspond to a thickness of the display device DD in the third direction DR3. The term "on a plane" used herein may mean being in a state when viewed in the third direction DR3. However, directions indicated by the first to third directions DR1, DR2 and DR3 are relative concepts and may be changed to other directions.

The electronic device ED may detect an external input applied from the outside. The external input may include various types of inputs provided from the outside of the electronic device ED. For example, the external input may include not only a touch by part of the body, such as a user’s hand, but also an external input (e.g., hovering) applied by approaching the electronic device ED or being adjacent thereto by a certain distance. In some aspects, the external input may include various types such as force, pressure, temperature, and light.

The electronic device ED may include a window WM and a housing HU. The window WM and the housing HU may be coupled to constitute an outer appearance of the electronic device ED.

The window WM may be divided into a transmission area TA and a bezel area BZA. The front surface of the electronic device ED may correspond to the transmission area TA and the bezel area BZA of the window WM.

The transmission area TA may be an area on which the image IM is displayed. The transmission area TA may be an optically transparent area. The user may see the image IM through the transmission area TA.

In this embodiment, the transmission area TA is illustrated in a rectangular shape with rounded vertices. However, this is illustrated as an example, and the transmission area TA may have various shapes and is not limited to any one embodiment.

The bezel area BZA may be an area having a relatively low light transmittance when compared to the transmission area TA. For example, the bezel area BZA may be provided as an area on which a material having a certain color is printed.

The bezel area BZA may be an area adjacent to the transmission area TA. The bezel area BZA may surround the transmission area TA. Accordingly, a shape of the transmission area TA may be defined substantially by the bezel area BZA. However, this is illustrated as an example, and the bezel area BZA may be disposed adjacent to a single side of the transmission area TA, or may be omitted.

Referring to FIGS. 2 and 3, the electronic device ED may include the display device DD, an electronic module EM, a power module PSM, and the housing HU. FIG. 3 illustrates the electronic device ED in brief, and the electronic device ED may further include a mechanical structure (e.g., a hinge) for controlling an operation (e.g., folding or rolling) of the display device DD.

The display device DD includes the window WM, a display module DM, a lower member LM, a driving chip DIC, and a printed circuit board PCB. The display module DM may include a display panel DP and an input sensing layer ISL.

The window WM may be disposed on the display module DM. The window WM may protect the display module DM. The window WM may include an optically transparent material. For example, the window WM may include glass, sapphire, plastic, or the like. An image provided from the display module DM may be provided for a user through the window WM.

The window WM may have a single-layer structure or a multilayer structure. For example, the window WM may include a plurality of plastic films coupled to each other, or a glass substrate and a plastic film coupled to each other.

The display module DM may include a front surface IS including an active area AA and a peripheral area NAA. The active area AA may be an area that is activated in response to an electrical signal. In this embodiment, the active area AA may be an area on which the image IM is displayed, and also an area through which the external input is detected.

The transmission area TA may overlap at least a portion of the active area AA. Accordingly, a user may see the image IM or provide an external input through the transmission area TA. However, this is illustrated as an example, and an area on which the image IM is displayed, and an area through which an external input is detected may be separated from each other within the active area AA, and are not limited to any one embodiment.

The peripheral area NAA may be an area that is covered by the bezel area BZA. The peripheral area NAA is adjacent to the active area AA. The peripheral area NAA may surround the active area AA. A driving circuit, a driving line, or the like for driving the active area AA may be disposed in the peripheral area NAA.

The display panel DP according to an embodiment of the inventive concept may be a liquid crystal display panel or an emissive display panel, but is not particularly limited. For example, the emissive display panel may be an organic light emitting display panel or a quantum dot light emitting display panel. A light emitting layer of the organic light emitting display panel may include an organic light emitting material. A light emitting layer of the quantum dot light emitting display panel may include a quantum dot, a quantum rod, or the like.

The display panel DP may be flexible. The term "flexible" indicates a characteristic of being capable of bending, and may include all from a fully folded structure to a structure capable of partially bending. For example, the display panel DP may be a curved display panel or a foldable display panel. However, the display panel DP is not limited thereto, and the display panel DP may be rigid.

The input sensing layer ISL may be disposed on the display panel DP. As illustrated in FIG. 2, the input sensing layer ISL may be directly disposed on the display panel DP. That is, the input sensing layer ISL may be provided on the display panel DP through a continuous process, and an adhesive film may not be disposed between the input sensing layer ISL and the display panel DP. However, embodiments of the present disclosure are not limited thereto, and an adhesive film may be disposed between the input sensing layer ISL and the display panel DP. The input sensing layer ISL may be manufactured through a separate process from the display panel DP, and then fixed to a top surface of the display panel DP by an adhesive film.

The input sensing layer ISL may detect an external input applied from the outside. As described herein, the input sensing layer ISL may detect an external input provided on the window WM.

The printed circuit board PCB may be disposed on one side of the display panel DP. The printed circuit board PCB may include a connection circuit board CF and a main circuit board MB.

The connection circuit board CF may connect the display panel DP to the main circuit board MB. The connection circuit board CF may be electrically connected to the display panel DP on one side adjacent to the display panel DP. The connection circuit board CF may be electrically connected to the main circuit board MB on the other side adjacent to the main circuit board MB.

One connection circuit board CF which connects the display panel DP to the main circuit board MB is illustrated in this embodiment. However, embodiments of the present disclosure are not limited thereto, and a plurality of connection circuit boards CF may be provided to connect the display panel DP to the main circuit board MB.

The connection circuit board CF may be a flexible printed circuit board. The connection circuit board CF may provide the display panel DP with an electrical signal for driving the display panel DP. The electrical signal may be generated from the connection circuit board CF or generated from the main circuit board MB.

The driving chip DIC may be mounted on the connection circuit board CF. The driving chip DIC may be mounted on the flexible printed circuit board and constitute a chip on film (COF). The driving chip DIC may include driving elements for driving a pixel of the display panel DP. The driving chip DIC may include a driving circuit, and the driving circuit may be provided as an integrated circuit. The driving circuit may include a driving controller, a data driver, a voltage generator, or the like.

The main circuit board MB may include a main controller. The main circuit board MB may include signal lines (not illustrated) for transmitting control signals and image signals received from the main controller to the connection circuit board CF and the display panel DP.

Although not illustrated, the printed circuit board PCB may further include an input circuit board electrically connected to the input sensing layer ISL. The input circuit board may connect the input sensing layer ISL to the main circuit board MB. In this embodiment, the input circuit board may be provided as a flexible circuit film and connect the input sensing layer ISL to the main circuit board MB. The input circuit board provides the input sensing layer ISL with an electrical signal for driving the input sensing layer ISL. The electrical signal may be generated from the input circuit board or generated from the main circuit board MB.

Each of the connection circuit board CF and the input circuit board may be connected to one main circuit board MB. One of the connection circuit board CF and the input circuit board may not be connected to the main circuit board MB, and is not limited to any one embodiment.

The lower member LM may be disposed below the display panel DP. The lower member LM may include a protective film which protects the display panel DP, a support member which supports the display panel DP, a digitizer, or the like.

The electronic module EM and the power module PSM may be disposed below the display module DM. The electronic module ELM and the power module PSM may be electrically connected to each other through a separate circuit board.

The power module PSM may supply power supportive of an operation of the electronic device ED. For example, the power module PSM may include a general battery module.

The electronic module EM may include a control module, a wireless communication module, an image input module, a sound input module, a sound output module, a memory, an external interface module, and the like. The electronic module EM may include a main circuit board, and the foregoing modules may be mounted on the main circuit board or electrically connected to the main circuit board through a flexible circuit board. The electronic module EM is electrically connected to the power module PSM.

Although not separately illustrated, the electronic device ED may further include an electro-optical module. The electro-optical module may be an electronic component for outputting or receiving an optical signal. The electro-optical module may include a camera module and/or a proximity sensor. The camera module may photograph an external image through a partial area of the display panel DP.

The housing HU illustrated in FIG. 3 is coupled to the display device DD, particularly to the window WM, and accommodates the other modules above. The housing HU is illustrated in a shape of one body, but is not limited thereto. The housing HU may include a plurality of portions (for example, a side edge portion and a bottom portion) that are coupled to each other. The housing HU may protect the display module DM accommodated in an inner space thereof against an external impact, and may prevent foreign matter or moisture from permeating the display module DM.

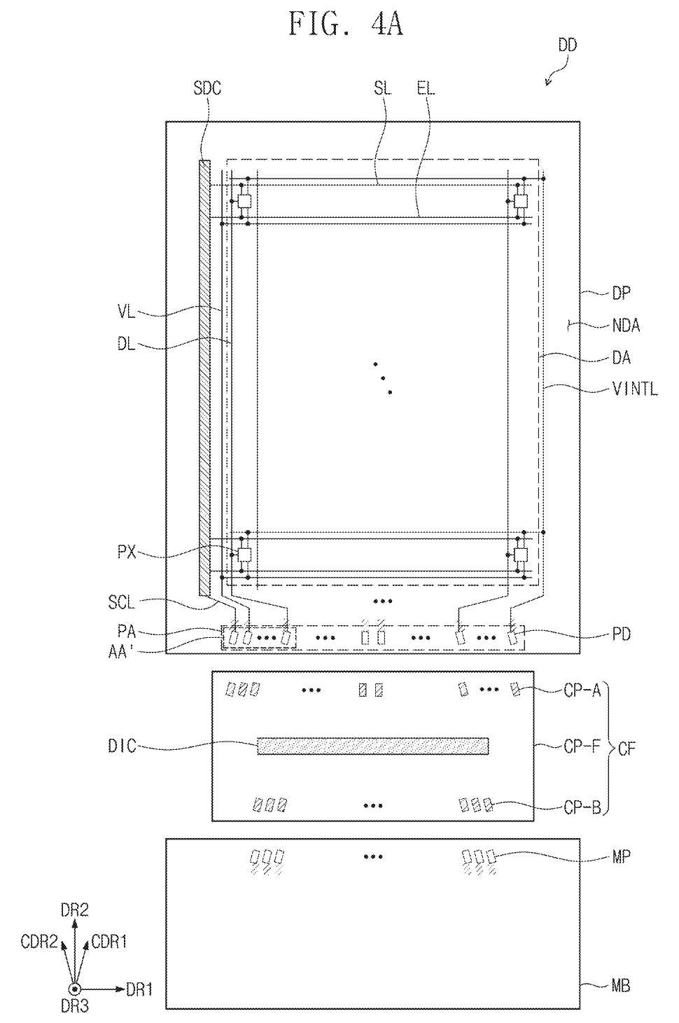

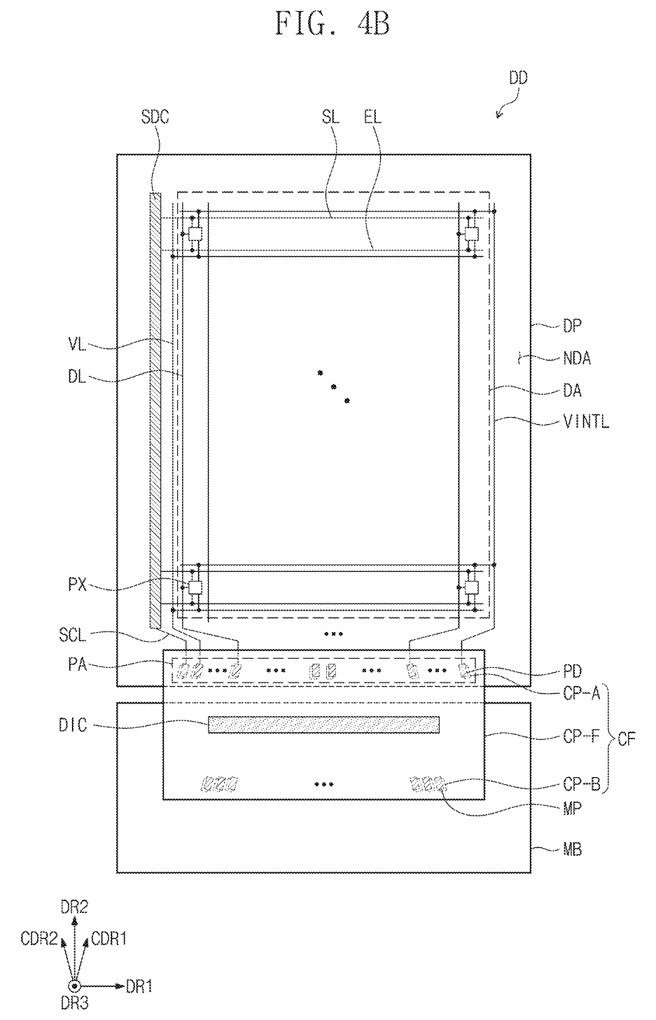

FIGS. 4A and 4B are plan views of a display device according to an embodiment of the inventive concept.

Referring to FIG. 4A, a display area DA and a non-display area NDA may be defined in a display panel DP on a plane. The display area DA may be an area on which an image is displayed. The non-display area NDA may be an area on which an image is not displayed. The non-display area EA-NDA may be an area adjacent to the display area DA. The non-display area EA-NDA may surround the display area DA, but the shape thereof is not limited thereto.

The display panel DP may include a plurality of pixels PX, a scan driving circuit SDC, a plurality of signal lines, and a plurality of pads PD. The display panel DP may include, as signal lines, scan lines SL, emission lines EL, data lines DL, a scan control line SCL, an initialization voltage line VINTL, and a voltage line VL.

Each of the pixels PX includes a display element and a thin film transistor electrically connected to the display element. The display element may include, for example, an organic light emitting diode. The pixels PX may be disposed in the display area DA. However, embodiments of the present disclosure are not limited thereto, and a portion of the pixels PX may be disposed in the non-display area NDA.

The pixels PX may be arranged in a matrix shape along the first direction DR1 and the second direction DR2 perpendicularly crossing each other. In an embodiment of the inventive concept, the pixels PX may include first to third pixels which display a red color, a green color, and a blue color, respectively. In an embodiment, the pixels PX may further include pixels which display partial white, cyan, and magenta, respectively.

The scan driving circuit SDC may be arranged adjacent to one side of the non-display area NDA. However, embodiments of the present disclosure are not limited thereto, and the scan driving circuit SDC may be disposed within the display area DA. The scan driving circuit SDC may generate a plurality of scan signals and a plurality of emission signals, and sequentially output the generated scan signals and emission signals to the scan lines SL and emission lines EL to be described later. The scan driving circuit SDC may further output another control signal to a driving circuit of the pixels PX.

Each of the scan lines SL may extend from the scan driving circuit SDC along the first direction DR1 and be connected to a corresponding pixel among the plurality of pixels PX. Each of the emission lines EL may extend from the scan driving circuit SDC along the first direction DR1 and be arranged parallel to a corresponding scan line among the scan lines SL. The scan lines SL and the emission lines EL may be connected to the scan driving circuit SDC.

Each of the data lines DL may extend along the second direction DR2 and be connected to a corresponding pixel among of the plurality of pixels PX. The scan control line SCL may provide control signals to the scan driving circuit SDC.

The initialization voltage line VINTL may provide an initialization voltage to the plurality of pixels PX. The voltage line VL may be connected to the plurality of pixels PX and provide a voltage to the plurality of pixels PX. The voltage line VL may include a plurality of lines extending along the first direction DR1 and a plurality of lines extending along the second direction DR2.

Some of the scan lines SL, the data lines DL, the emission lines EL, the scan control line SCL, the initialization voltage line VINTL, and the voltage line VL may be disposed at the same layer, and other some thereof may be disposed at a different layer.

The pads PD may be disposed in the non-display area NDA. Specifically, the pads PD may be disposed in a pad area PA of the non-display area NDA. The pads PD may be arranged parallel to each other in the first direction DR1. In this embodiment, the pads PD are illustrated and described as being arranged in one row along the first direction DR1, but are not limited thereto. For example, the pads PD may be arranged in two or more rows or arranged in a zigzag shape. The pads PD may be connected to the data lines DL, the scan control line SCL, the initialization voltage line VINTL, and the voltage line VL.

A connection circuit board CF may include a connection base layer CP-F, a plurality of connection pads CP-A, and a plurality of substrate connection pads CP-B.

The connection base layer CP-F may be an insulating layer on which the plurality of connection pads CP-A and the plurality of substrate connection pads CP-B are disposed. The connection base layer CP-F may include a flexible film.

The connection pads CP-A may be arranged on one side of the connection base layer CP-F adjacent to the display panel DP along the first direction DR1. The connection pads CP-A may be connected to the pads PD of the display panel DP which correspond to the connection pads CP-A, respectively.

The pads PD may be arranged on a front surface of the display panel DP, and the connection pads CP-A may be arranged on a rear surface of the connection base layer CP-F. However, embodiments of the present disclosure are not limited thereto. The pads PD may be arranged on a rear surface of the display panel DP, and the connection pads CP-A may be arranged on a front surface of the connection base layer CP-F.

The substrate connection pads CP-B may be arranged on the other side of the connection base layer CP-F adjacent to a main circuit board MB along the first direction DR1. The substrate connection pads CP-B may be spaced apart from the connection pads CP-A along the second direction DR2. The substrate connection pads CP-B may be arranged on the rear surface of the connection base layer CP-F. However, embodiments of the present disclosure are not limited thereto, and the substrate connection pads CP-B may be arranged on the front surface of the connection base layer CP-F.

The connection circuit board CF may include a plurality of lines. Each of the plurality of lines may transmit an electrical signal to components respectively connected to one end and the other end of the line. The plurality of lines may include lines which electrically connect the connection pads CP-A to a driving chip DIC, and lines which electrically connect the substrate connection pads CP-B to the driving chip DIC. The plurality of lines may be disposed on the connection base layer CP-F.

The main circuit board MB may include a plurality of substrate pads MP. The main circuit board MB may include a plurality of lines connected to the substrate pads MP.

The substrate pads MP may be arranged on one side of the main circuit board MB adjacent to the connection circuit board CF along the first direction DR1. The substrate pads MP may be arranged on a front surface of the main circuit board MB. However, embodiments of the present disclosure are not limited thereto, and the substrate pads MP may be arranged on a rear surface of the main circuit board MB.

The substrate pads MP may be connected to the substrate connection pads CP-B of the connection circuit board CF which correspond to the substrate pads MP, respectively. The substrate pads MP may be electrically connected to a main controller through lines, and may receive control signals and image signals from the main controller. The substrate pads MP may transmit the received signals to the substrate connection pads CP-B.

According to an embodiment of the inventive concept, the plurality of pads PD may extend in a direction inclined at a first angle with respect to the second direction DR2. Specifically, the plurality of pads PD may extend in a first diagonal direction CDR1 or a second diagonal direction CDR2. For example, the plurality of pads PD disposed on the left of the pad area PA may extend in the first diagonal direction CDR1 which forms an acute angle clockwise with respect to the second direction DR2, and the plurality of pads PD disposed on the right of the pad area PA may extend in the second diagonal direction CDR2 which forms an acute angle counterclockwise with respect to the second direction DR2.

In some aspects, the plurality of connection pads CP-A, the plurality of substrate connection pads CP-B, and the plurality of substrate pads MP may correspond to the plurality of pads PD, respectively, and extend in the direction inclined at the first angle with respect to the second direction DR2.

Referring to FIG. 4B, the connection circuit board CF may be attached to the pad area PA of the display panel DP. Although not illustrated, a conductive adhesive film may be disposed between the display panel DP and the connection circuit board CF. For example, the conductive adhesive film may include an anisotropic conductive film (ACF). In some aspects, the connection circuit board CF may be attached to the main circuit board MB.

In an embodiment of the inventive concept, the plurality of pads PD and the plurality of connection pads CP-A may be mis-aligned with each other during the attaching of the connection circuit board CF to the pad area PA of the display panel DP. Thus, a misalignment inspection of the plurality of pads PD and connection pads CP-A may be carried out. This will be described later in detail.

FIG. 4B illustrates the pads misaligned with each other for better understanding of connections between the pads PD and the connection pads CP-A and connections between the substrate pads MP and the substrate connection pads CP-B, but the pads may be connected to corresponding pads to overlap the corresponding pads, respectively.

When the pads PD and the connection pads CP-A are sufficiently and fully connected to each other, control signals and image signal received from a driving circuit of the driving chip DIC may be transmitted without distortion to the display panel DP. When the substrate pads MP and the substrate connection pads CP-B are sufficiently and fully connected to each other, control signals and image signal received from the main controller of the main circuit board MB may be transmitted without distortion to the driving circuit of the driving chip DIC.

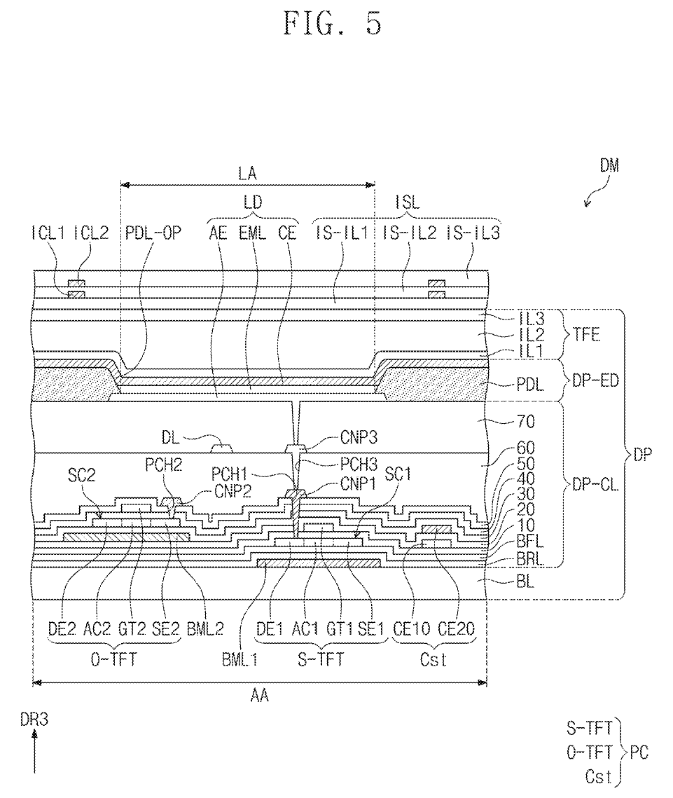

FIG. 5 is a cross-sectional view of a display module according to an embodiment of the inventive concept. For example, FIG. 5 illustrates a cross-section of a display module DM corresponding to the pixel PX in FIG. 4A.

Referring to FIG. 5, a pixel driving circuit PC which drives a light emitting element LD may include a plurality of pixel driving elements. The pixel driving circuit PC may include a plurality of transistors S-TFT and O-TFT and a capacitor Cst. The plurality of transistors S-TFT and O-TFT may include a silicon transistor S-TFT and an oxide transistor O-TFT. As an example, FIG. 5 illustrates the silicon transistor S-TFT and the oxide transistor O-TFT. The pixel driving circuit PC in FIG. 5 is just one embodiment, and components of the pixel driver circuit PC are not necessarily limited thereto. The pixel driving circuit PC may include one type of transistor among the silicon transistor S-TFT and the oxide transistor O-TFT.

FIG. 5 illustrates a base layer BL having a single-layer structure. The base layer BL may include a synthetic resin such as polyimide. A synthetic resin layer may be applied onto a work substrate (or a carrier substrate) to form the base layer BL. In an example in which the display module DM is completed through a follow-up process, the work substrate may be removed.

A first shielding electrode (or shielding electrode) BML1 may be disposed on the base layer BL. The first shielding electrode BML1 may receive a bias voltage. The first shielding electrode BML1 may receive a first power voltage. The first shielding electrode BML1 may prevent an electrical potential due to a polarization phenomenon from affecting the silicon transistor S-TFT. The first shielding electrode BML1 may prevent external light from reaching the silicon transistor S-TFT. In an embodiment of the inventive concept, the first shielding pattern BML1 may be a floating electrode having a shape isolated from another electrode or a line. The first shielding electrode BML1 may be arranged to correspond to the silicon transistor S-TFT. The first shielding electrode BML1 may include a metal, for example, molybdenum.

A barrier layer BRL may be disposed on the base layer BL and the first shielding electrode BML1. The barrier layer BRL prevents foreign matter from being introduced from the outside. The barrier layer BRL may include at least one inorganic layer. The barrier layer BRL may include a silicon oxide layer and a silicon nitride layer. Each of the silicon oxide layer and the silicon nitride layer may be provided in plurality, and the silicon oxide layers and the silicon nitride layers may be alternately stacked.

A buffer layer BFL may be disposed on the barrier layer BRL. The buffer layer BFL may prevent a phenomenon in which metal atoms or impurities spread from the base layer BL to a first semiconductor pattern SC1 above the buffer layer BFL. The buffer layer BFL may include at least one inorganic layer. The buffer layer BFL may include a silicon oxide layer and a silicon nitride layer.

The first semiconductor pattern SC1 may be disposed on the buffer layer BFL. The first semiconductor pattern SC1 may include a silicon semiconductor. For example, the silicon semiconductor may include an amorphous silicon, a polycrystalline silicon, or the like. For example, the first semiconductor pattern SC1 may include a low-temperature polysilicon.

The first semiconductor pattern SC1 may have different electrical properties according to whether the first semiconductor pattern SC1 is doped or not. The first semiconductor pattern SC1 may include a first region with high conductivity and a second region with low conductivity. The first region may be doped with an n-type dopant or a p-type dopant. A p-type transistor may include a doped region doped with the p-type dopant, and an n-type transistor may include a doped region doped with the n-type dopant. The second region may be a non-doped region, or a region doped at a lower concentration than the first region. In this embodiment, the first semiconductor pattern SC1 may be the n-type transistor.

The conductivity of the first region may be higher than the conductivity of the second region, and the first region may substantially serve as an electrode or a signal line. The second region may substantially correspond to a channel region (or an active region) of a transistor. In other words, one portion of the first semiconductor pattern SC1 may be a channel of a transistor, another portion thereof may be a source or drain of the transistor, and still another portion thereof may be a connection electrode or a connection signal line.

A source region SE1, a channel region AC1 (or active region), and a drain region DE1 of the silicon transistor S-TFT may be provided from the first semiconductor pattern SC1. The source region SE1 and the drain region DE1 may extend from the channel region AC1 in opposite directions on a cross-section.

A first insulating layer 10 may be disposed on the buffer layer BFL. The first insulating layer 10 may cover the first semiconductor pattern SC1. The first insulating layer 10 may be an inorganic layer. The first insulating layer 10 may be a silicon oxide layer having a single-layer structure. Not only the first insulating layer 10,but also an inorganic layer of a circuit layer DP-CL to be described later, may each have a single-layer structure or a multilayer structure and may each include at least one of the materials described herein. However, embodiments of the present disclosure are not limited thereto.

A gate (or gate electrode) GT1 of the silicon transistor S-TFT is disposed on the first insulating layer 10. The gate GT1 may be a portion of a metal pattern. The gate GT1 overlaps the channel region AC1. The gate GT1 may serve as a mask in a process of doping the first semiconductor pattern SC1. A first electrode CE10 of a storage capacitor Cst is disposed on the first insulating layer 10. Unlike an embodiment illustrated in FIG. 5, the first electrode CE10 and the gate GT1 may have a shape of one body.

A second insulating layer 20 may be disposed on the first insulating layer 10 and cover the gate GT1. In an embodiment of the inventive concept, an upper electrode overlapping the gate GT1 may be further disposed on the second insulating layer 20. A second electrode CE20 overlapping the first electrode CE10 may be disposed on the second insulating layer 20. The upper electrode and the second electrode CE20 may have a shape of one body on a plane.

A second shielding electrode BML2 is disposed on the second insulating layer 20. The second shielding electrode BML2 may be arranged to correspond to the oxide transistor O-TFT. The second shielding electrode BML2 may be omitted in an embodiment of the inventive concept. According to an embodiment of the inventive concept, the first shielding electrode BML1 may extend to below the oxide transistor O-TFT and replace the second shielding electrode BML2.

A third insulating layer 30 may be disposed on the second insulating layer 20. A second semiconductor pattern SC2 may be disposed on the third insulating layer 30. The second semiconductor pattern SC2 may include a channel region AC2 of the oxide transistor O-TFT. The second semiconductor pattern SC2 may include a metal oxide semiconductor. The second semiconductor pattern SC2 may include a transparent conductive oxide (TCO) such as indium tin oxide (ITO), indium zinc oxide (IZO), indium gallium zinc oxide (IGZO), zinc oxide (ZnOₓ), or indium oxide (In₂O₃).

The metal oxide semiconductor may include a plurality of regions SE2, AC2 and DE2 divided according to whether the transparent conductive oxide is reduced or not. A region in which the transparent conductive oxide is reduced (hereinafter referred to as a reduction region), has higher conductivity than a region in which the transparent conductive oxide is not reduced (hereinafter referred to as a non-reduction region). The reduction region substantially serves as a signal line or a source/drain of a transistor. The non-reduction region substantially corresponds to a semiconductor region (or channel region) of the transistor. In other words, a partial region of the second semiconductor pattern SC2 may be the semiconductor region of the transistor, another partial region thereof may be a source region SE2/ drain region DE2 of the transistor, and still another portion thereof may be a signal transmitting region.

A fourth insulating layer 40 may be disposed on the third insulating layer 30. As illustrated in FIG. 5, the fourth insulating layer 40 may cover the second semiconductor pattern SC2. In an embodiment of the inventive concept, the fourth insulating layer 40 may be an insulating pattern that overlaps a gate GT2 of the oxide transistor O-TFT and exposes each of the source region SE2 and the drain region DE2 of the oxide transistor O-TFT.

The gate GT2 of the oxide transistor O-TFT is disposed on the fourth insulating layer 40. The gate GT2 of the oxide transistor O-TFT may be a portion of a metal pattern. The gate GT2 of the oxide transistor O-TFT overlaps the channel region AC2.

A fifth insulating layer 50 may be disposed on the fourth insulating layer 40, and the fifth insulating layer 50 may cover the gate GT2. Each of the first insulating layer 10 to the fifth insulating layer 50 may be an inorganic layer.

A conductive layer may be disposed on the fifth insulating layer 50. In the inventive concept, the conductive layer may include a first connection pattern CNP1 and a second connection pattern CNP2. The first connection pattern CNP1 and the second connection pattern CNP2 may be formed through the same process and thus have the same material and the same stack structure as one another. The first connection pattern CNP1 may be connected to the drain region DE1 of the silicon transistor S-TFT through a first pixel contact hole PCH1 passing through the first to fifth insulating layers 10, 20, 30, 40 and 50. The second connection pattern CNP2 may be connected to the source region SE2 of the oxide transistor O-TFT through a second pixel contact hole PCH2 passing through the fourth and fifth insulating layers 40 and 50. The relationships of connections of the first connection pattern CNP1 and the second connection pattern CNP2 to the silicon transistor S-TFT and the oxide transistor O-TFT are not necessarily limited thereto.

A sixth insulating layer 60 may be disposed on the fifth insulating layer 50. A third connection pattern CNP3 may be disposed on the sixth insulating layer 60. The third connection pattern CNP3 may be connected to the first connection pattern CNP1 through a third pixel contact hole PCH3 passing through the sixth insulating layer 60. A data line DL may be disposed on the sixth insulating layer 60. A seventh insulating layer 70 may be disposed on the sixth insulating layer 60, and cover the third connection pattern CNP3 and the data line DL. The first connection pattern CNP3 and the data line DL may be formed through the same process and thus have the same material and the same stack structure. Each of the sixth insulating layer 60 and the seventh insulating layer 70 may be an organic layer.

The first shielding electrode BML1, the gate GT1 of the silicon transistor S-TFT, the second electrode CE20, and the gate GT2 of the oxide transistor O-TFT may include molybdenum (Mo), a molybdenum-containing alloy, titanium (Ti), or a titanium-containing alloy, each of which has good heat resistance. The first connection pattern CNP1 and the second connection pattern CNP2 may include aluminum having high electrical conductivity. The first connection pattern CNP1 and the second connection pattern CNP2 may each have a three-layer structure in which titanium/aluminum/titanium are stacked.

The light emitting element LD may include an anode AE (or first electrode), a light emitting layer EML, and a cathode CE (or second electrode). The anode AE of the light emitting element LD may be disposed on the seventh insulating layer 70. The anode AE may be a transmissive electrode, a semi-transmissive electrode, or a reflective electrode. The anode AE may include a stack structure of ITO/Ag/ITO stacked in sequence. Positions of the anode AE and the cathode CE may be exchanged.

A pixel defining film PDL may be disposed on the seventh insulating layer 70. The pixel defining film PDL may be an organic layer. The pixel defining film PDL may have a light absorbing property, and, for example, the pixel defining film PDL may have a black color. The pixel defining film PDL may include a black component (a black coloring agent). The black component may include a black dye or a black pigment. The black component may include a carbon black, a metal such as chrome, or an oxide thereof. The pixel defining film PDL may correspond to a light blocking pattern having a light blocking characteristic.

The pixel defining layer PDL may cover a portion of the anode AE. For example, an opening portion PDL-OP that exposes a portion of the anode AE may be defined in the pixel defining layer PDL. A light emitting area LA may be defined so as to correspond to the opening portion PDL-OP. In an embodiment of the inventive concept, a hole control layer may be disposed between the anode AE and the light emitting layer EML. The hole control layer may include a hole transport layer and further include a hole injection layer. An electron control layer may be disposed between the light emitting layer EML and the cathode CE. The electron control layer may include an electron transport layer and further include an electron injection layer.

An encapsulation layer TFE may cover the light emitting element LD. The encapsulation layer TFE may include a first encapsulation insulating layer IL1, a second encapsulation insulating layer IL2, and a third encapsulation insulating layer IL3. However, embodiments of the present disclosure are not limited thereto, and the encapsulation layer TFE may further include a plurality of inorganic layers and organic layers.

The first encapsulation insulating layer IL1 may be an inorganic layer. The first encapsulation insulating layer IL1 may prevent outside moisture or oxygen from penetrating the light emitting element LD. For example, the first encapsulation insulating layer IL1 may include a silicon nitride, a silicon oxide, or a compound as a combination thereof. The first encapsulation insulating layer IL1 may be formed through a chemical vapor deposition process.

The second encapsulation insulating layer IL2 may be an organic layer. The second encapsulation insulating layer IL2 may be disposed on the first encapsulation insulating layer IL1 to be in contact with the first encapsulation insulating layer IL1. The second encapsulation insulating layer IL2 may provide a flat surface on the first encapsulation insulating layer IL1. Unevenness formed on a top surface of the first encapsulation insulating layer IL1, particles present on the first encapsulation insulating layer IL1, or the like may be covered by the second encapsulation insulating layer IL2, thereby preventing a surface state of the top surface of the first encapsulation insulating layer IL1 from affecting components disposed on the second encapsulation insulating layer IL2. In some aspects, the second encapsulation insulating layer IL2 may alleviate stress between layers that are in contact with each other. The second encapsulation insulating layer IL2 may be formed through a solution process such as spin coating, slit coating, or inkjet process.

The third encapsulation insulating layer IL3 is disposed on the second encapsulation insulating layer IL2 and covers the second encapsulation insulating layer IL2. The third encapsulation insulating layer IL3 may be stably disposed on a relatively flat surface compared to a case in which the third encapsulation insulating layer IL3 is disposed on the first encapsulation insulating layer IL1. The third encapsulation insulating layer IL3 may encapsulate moisture or the like emitted from the second encapsulation insulating layer IL2 and prevent the same from being introduced into the outside.

The third encapsulation insulating layer IL3 may be optically transparent. For example, the third encapsulation insulating layer IL3 may have a visible light transmittance of about 90% or more. The third encapsulation insulating layer IL3 may have a relatively higher light transmittance than the first encapsulation insulating layer IL1. The third encapsulation insulating layer IL3 may be an inorganic layer. The third encapsulation insulating layer IL3 may include a silicon oxide (SiOₓ) or a silicon oxynitride (SiON). The third encapsulation insulating layer IL3 may be formed through a chemical vapor deposition process. Each of the first encapsulation insulating layer IL1, the second encapsulation insulating layer IL2, and the third encapsulation insulating layer IL3 may include a plurality of layers, and is not limited to any one embodiment.

An input sensing layer ISL may include at least one conductive layer (or at least one sensor conductive layer) and at least one insulating layer (or at least one sensor insulating layer). In this embodiment, the input sensing layer ISL may include a first insulating layer IS-IL1, a first conductive layer ICL1, a second insulating layer IS-IL2, a second conductive layer ICL2, and a third insulating layer IS-IL3. A conductive line of the first conductive layer ICL1 and a conductive line of the second conductive layer ICL2 are illustrated in brief in FIG. 5.

The first insulating layer IS-IL1 may be directly disposed on the display panel DP. The first insulating layer IS-IL1 may be an inorganic layer including at least one of silicon nitride, silicon oxynitride, or silicon oxide. Each of the first conductive layer ICL1 and the second conductive layer ICL2 may have a single-layer structure, or have a multilayer structure in which layers are stacked in the third direction DR3. The first conductive layer ICL1 and the second conductive layer ICL2 may include conductive lines which define a mesh-shaped electrode. The conductive line of the first conductive layer ICL1 and the conductive line of the second conductive layer ICL2 may be connected to each other through a contact hole passing through the second insulating layer IS-IL2 or may not be connected to each other. The connection relationship between the conductive line of the first conductive layer ICL1 and the conductive line of the second conductive layer ICL2 may be determined according to a type of sensor provided as the input sensing layer ISL.

The first conductive layer ICL1 and the second conductive layer ICL2 each having a single-layer structure may include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnOₓ), or indium zinc tin oxide (IZTO). In some aspects, the transparent conductive layer may include a conductive polymer such as PEDOT, metal nanowire, graphene, or the like.

The first conductive layer ICL1 and the second conductive layer ICL2 each having a multilayer structure may include metal layers. The metal layers may have, for example, a three-layer structure of titanium/aluminum/titanium. The conductive layer having a multilayer structure may include at least one metal layer and at least one transparent conductive layer. The second insulating layer IS-IL2 may be disposed between the first conductive layer ICL1 and the second conductive layer ICL2. The third insulating layer IS-IL3 may cover the second conductive layer ICL2. The third insulating layer IS-IL3 may be omitted in an embodiment of the inventive concept. The second insulating layer IS-IL2 and the third insulating layer IS-IL3 may include an inorganic layer or an organic layer.

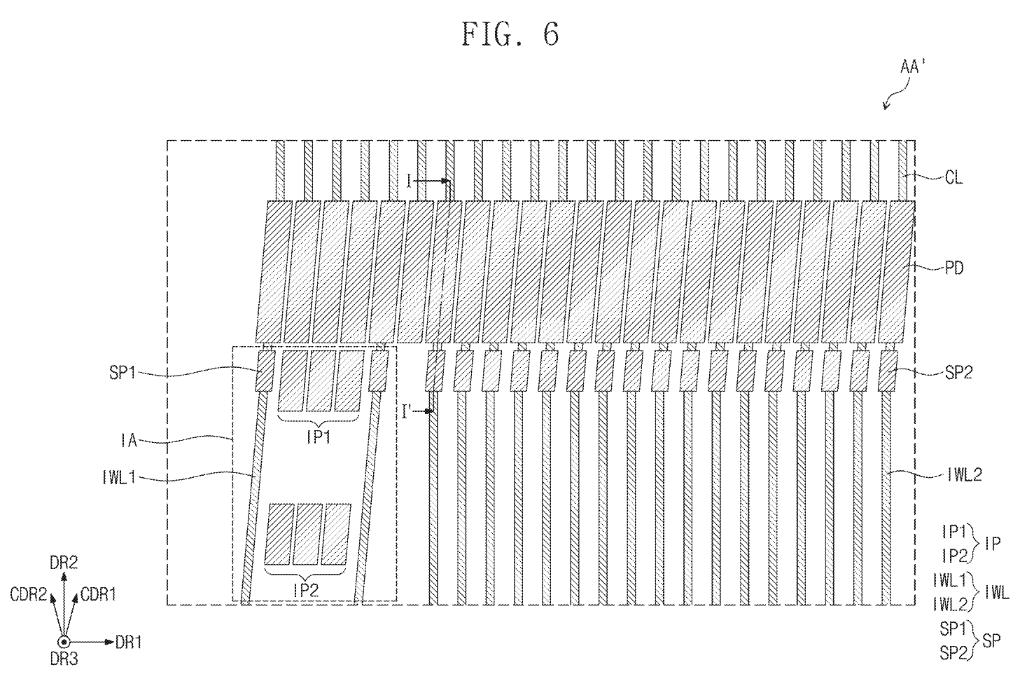

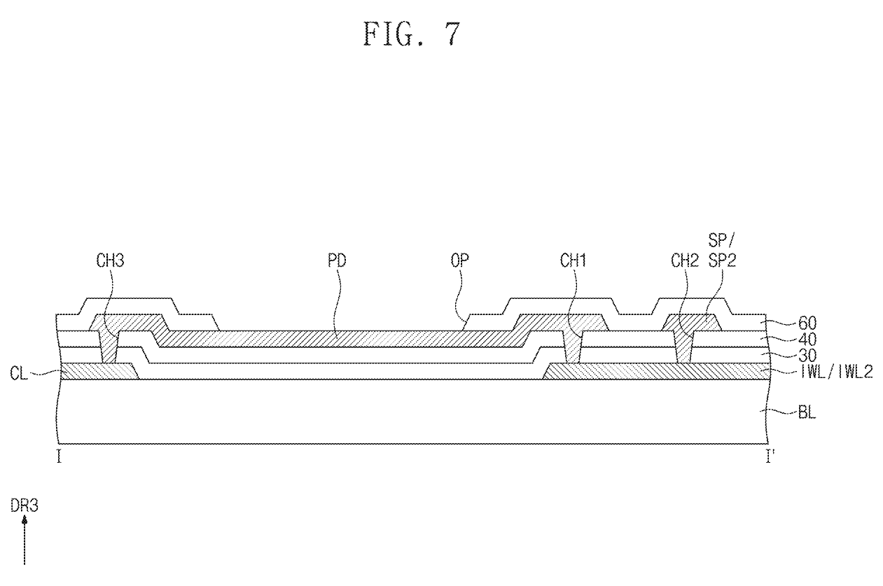

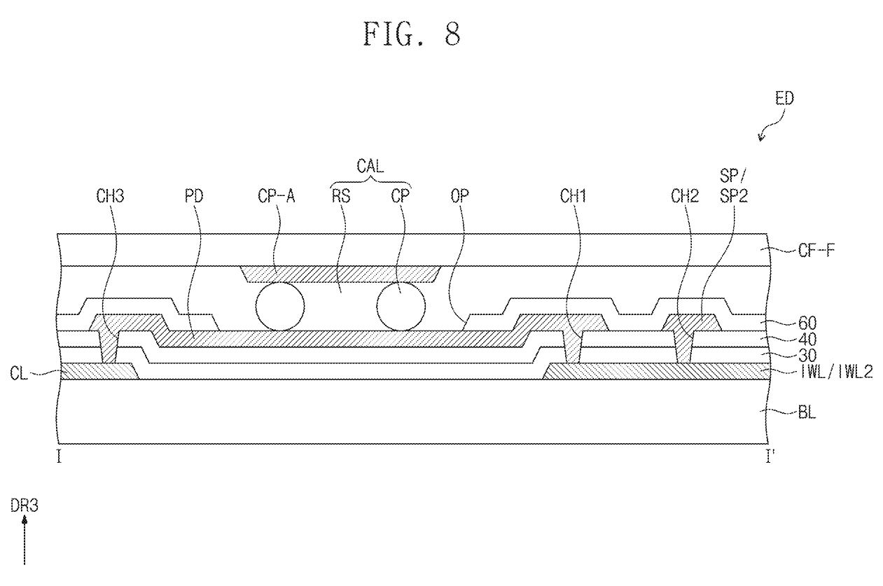

FIG. 6 is an enlarged view of area AA' illustrated in FIG. 4A. FIG. 7 is a cross-sectional view taken along line I-I' illustrated in FIG. 6. FIG. 8 is a cross-sectional view of a portion of an electronic device according to an embodiment of the inventive concept. FIG. 8 illustrates an example of a cross-section of an electronic device ED in which a connection circuit board CF is bonded onto the display panel DP illustrated in FIG. 3. The contents in common with the contents set forth above will be omitted.

Referring to FIGS. 6 and 7 together, a plurality of pads PD may be electrically connected to a plurality of connection lines CL extending in the second direction DR2. For example, the plurality of pads PD may be electrically connected to the plurality of connection lines CL through respective third contact holes CH3 defined to pass through third and fourth insulating layers 30 and 40. The plurality of connection lines CL may correspond to the data lines DL, the scan control line SCL, the initialization voltage line VINTL, and the voltage line VL which are the signal lines illustrated in FIG. 4A. The plurality of pads PD may transmit signals respectively corresponding to pixels PX through the plurality of connection lines CL.

The plurality of pads PD may be electrically connected to an inspection line IWL extending in a direction opposite to the second direction DR2. For example, the plurality of pads PD may be electrically connected to the inspection line IWL through respective first contact holes CH1 defined to pass through the third and fourth insulating layers 30 and 40. The inspection line IWL may be provided in plurality to correspond to the plurality of pads PD. The inspection line IWL may be disposed at the same layer as the plurality of connection lines CL. The inspection line IWL and the plurality of connection lines CL may include the same material as the second shielding electrode BML2 illustrated in FIG. 5. That is, the inspection line IWL and the plurality of connection lines CL may be formed through the same process as the second shielding electrode BML2.

The inspection line IWL may transmit an inspection signal to the plurality of pads PD. The inspection signal is a signal which checks whether the plurality of pads PD are electrically connected to the plurality of connection lines CL, respectively, and may check for shorts between the plurality of pads PD and the plurality of connection lines CL.

A plurality of sub-patterns SP may be disposed between the plurality of pads PD and the inspection line IWL. The plurality of sub-patterns SP may be referred to as a rework pattern. The plurality of sub-patterns SP may include the same material as the plurality of pads PD. The plurality of sub-patterns SP may be electrically connected to the inspection line IWL. For example, the plurality of sub-patterns SP may be electrically connected to the inspection line IWL through respective second contact holes CH2 defined to pass through the third and fourth insulating layers 30 and 40. The plurality of sub-patterns SP may be disposed at the same layer as the plurality of pads PD. The plurality of sub-patterns SP and the plurality of pads PD may include the same material as the first connection pattern CNP1 and the second connection pattern CNP2 illustrated in FIG. 5. That is, the plurality of sub-patterns SP and the plurality of pads PD may be formed through the same processes as the first connection pattern CNP1 and the second connection pattern CNP2, respectively.

According to an embodiment of the inventive concept, the plurality of sub-patterns SP may extend in the first diagonal direction CDR1 to correspond to the plurality of pads PD. That is, each of the plurality of sub-patterns SP may extend in the same direction as a corresponding pad PD among the plurality of pads PD. In an example in which the plurality of sub-patterns SP extend in the second direction DR2, the plurality of pads PD may be affected by noise generated from the plurality of sub-patterns SP. However, as the plurality of sub-patterns SP according to an embodiment of the inventive concept extend in the first diagonal direction CDR1 to correspond to the plurality of pads PD, the noise transmitted to the plurality of pads PD from the plurality of sub-patterns SP may be reduced.

Referring to FIGS. 7 and 8 together, the plurality of pads PD may be exposed to the outside by respective opening portions OP defined in a sixth insulating layer 60. The connection circuit board CF may include a connection base layer CP-F and a plurality of connection pads CP-A. The plurality of connection pads CP-A may be disposed on a rear surface of the connection base layer CP-F.

The plurality of connection pads CP-A may be electrically connected to the plurality of pads PD exposed to the outside by the opening portions OP. Specifically, the plurality of connection pads CP-A may be electrically connected to the plurality of pads PD through a conductive adhesive layer CAL. The conductive adhesive layer CAL may include an adhesive resin RS and conductive particles CP dispersed in the adhesive resin RS. In an embodiment, the conductive adhesive layer CAL may be an anisotropic conductive adhesive.

The adhesive resin RS may be filled between the conductive particles CP, and couple the connection circuit board CF (see FIG. 3) to the display panel DP (see FIG. 3). The adhesive resin RS may include a polymer material. For example, the adhesive resin RS may include at least one of acrylic polymer, silicon-based polymer, urethane-based polymer, or imide-based polymer. The adhesive resin RS may be a portion formed by heat curing or photocuring a base resin such as acrylic resin, silicon-based resin, urethane-based resin, or imide-based resin.

The conductive particles CP may be metal particles, alloy particles in which a plurality of metals are mixed, or the like. For example, the conductive particles CP may be metal or metal alloy particles including at least one of silver, copper, bismuth, zinc, indium, tin, nickel, cobalt, chrome, or iron. Alternatively, the conductive particles CP may each have a core portion including a polymer resin or the like, and a coating layer surrounding the core portion and including a conductive material.

The conductive particles CP may be arranged in the adhesive resin RS between the pads PD and the plurality of connection pads CP-A corresponding to each other. The conductive particles CP may have an anisotropy such that a current may flow in a pressing direction upon pressing during the bonding of the connection circuit board CF (see FIG. 3). Accordingly, the pads PD may be respectively electrically connected to the connection pads CP-A through the conductive particles CP.

Referring to FIG. 6 again, the pad area PA (see FIG. 4A) according to an embodiment of the inventive concept may include an inspection area IA. The inspection area IA may be defined at the outermost portion of the pad area PA on a plane, specifically on each of opposite sides of the pad area PA in the first direction DR1. The inspection area IA may be an area for securing bonding reliability by checking alignment between the plurality of connection pads CP-A (see FIG. 4A) of the connection circuit board CF (see FIG. 4A) and the pads PD in a process of bonding the connection circuit board CF (see FIG. 4A) connected to the pad area PA.

An inspection pattern IP may be disposed in the inspection area IA. The inspection pattern IP may include portions having the same shape as each of the pads PD. Specifically, the inspection patterns IP may be aligned in the first direction DR1 and extend in the first diagonal direction CDR1. The inspection patterns IP may be disposed at the same layer as the pads PD and include the same material as the pads PD. In the display device DD (see FIG. 2) according to an embodiment of the inventive concept, the inspection patterns IP extending in the same direction as the pads PD may be defined in the inspection area IA. The inspection patterns IP thereby support checking whether the pads PD are arranged and whether, after the bonding process, the pads PD are aligned with the connection pads CP-A extending in the first diagonal direction CDR1 that is the same direction as the direction in which the pads PD extend. Accordingly, process reliability of the display device DD may be improved.

According to an embodiment of the inventive concept, the inspection patterns IP may include a first inspection pattern IP1 and a second inspection pattern IP2 which are spaced apart from each other in the first diagonal direction CDR1. Each of the first inspection pattern IP1 and the second inspection pattern IP2 may be provided in plurality. The first inspection patterns IP1 and the second inspection patterns IP2 may have the same shape.

The plurality of sub-patterns SP may include a first sub-pattern SP1 and a second sub-pattern SP2. The first sub-pattern SP1 may be disposed in the inspection area IA. The first sub-pattern SP1 and the second sub-pattern SP2 may be spaced apart from each other in the first direction DR1. The first sub-pattern SP1 may be provided in plurality. The second sub-pattern SP2 may be provided in plurality. The first inspection pattern IP1 may be disposed between two sub-patterns SP1 as illustrated in FIG. 6.

The inspection line IWL may include a first inspection line IWL1 and a second inspection line IWL2. The first inspection line IWL1 may be disposed in the inspection area IA. According to an embodiment of the inventive concept, the first inspection line IWL1 may extend in the first diagonal direction CDR1. That is, the first inspection line IWL1 extending in the first diagonal direction CDR1 in the inspection area IA may be used to check whether the pads PD are arranged or not.

The first inspection line IWL1 and the second inspection line IWL2 may be spaced apart from each other in the first direction DR1. Each of the first inspection line IWL1 and the second inspection line IWL2 may be provided in plurality. The second inspection pattern IP2 may be disposed between two first inspection lines IWL1 as illustrated in FIG. 6. Unlike the first inspection line IWL1, the second inspection line IWL2 may extend in the second direction DR2.

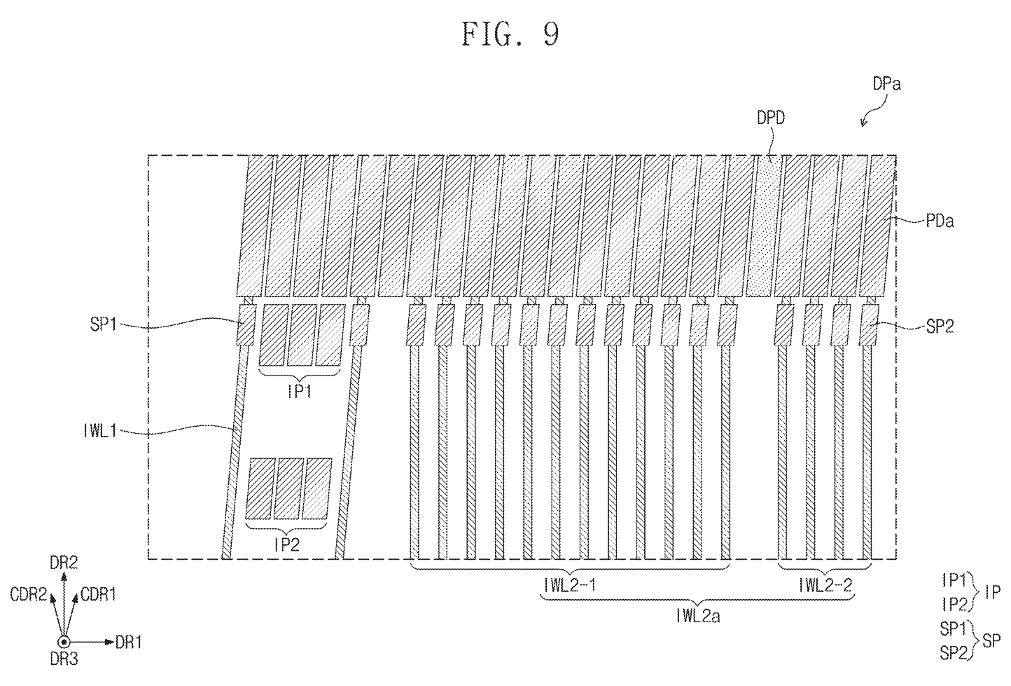

FIG. 9 is a view illustrating a portion of a display panel DPa according to an embodiment of the inventive concept.

Referring to FIG. 9, pads PDa according to an embodiment of the inventive concept may further include a dummy pad DPD. The dummy pad DPD may be disposed between the plurality of pads PDa. The dummy pad DPD may not be substantially connected to the signal lines illustrated in FIG. 4A (e.g., the data lines DL, the scan control line SCL, the initialization voltage line VINTL, and the voltage line VL). That is, the dummy pad DPD is a pad which is formed through the same process as the pads PDa in the formation of the pads PDa and provided for uniform arrangement of the pads PDa, and may be a floating electrode.

According to an embodiment of the inventive concept, a sub-pattern SP (e.g., the second sub-pattern SP2) corresponding to the dummy pad DPD may not be defined. Likewise, a second inspection line IWL2a corresponding to the dummy pad DPD may not be defined. The second inspection line IWL2a may include a (2-1)-th inspection line IWL2-1 and a (2-2)-th inspection line IWL2-2 which are spaced apart from each other in the first direction DR1.

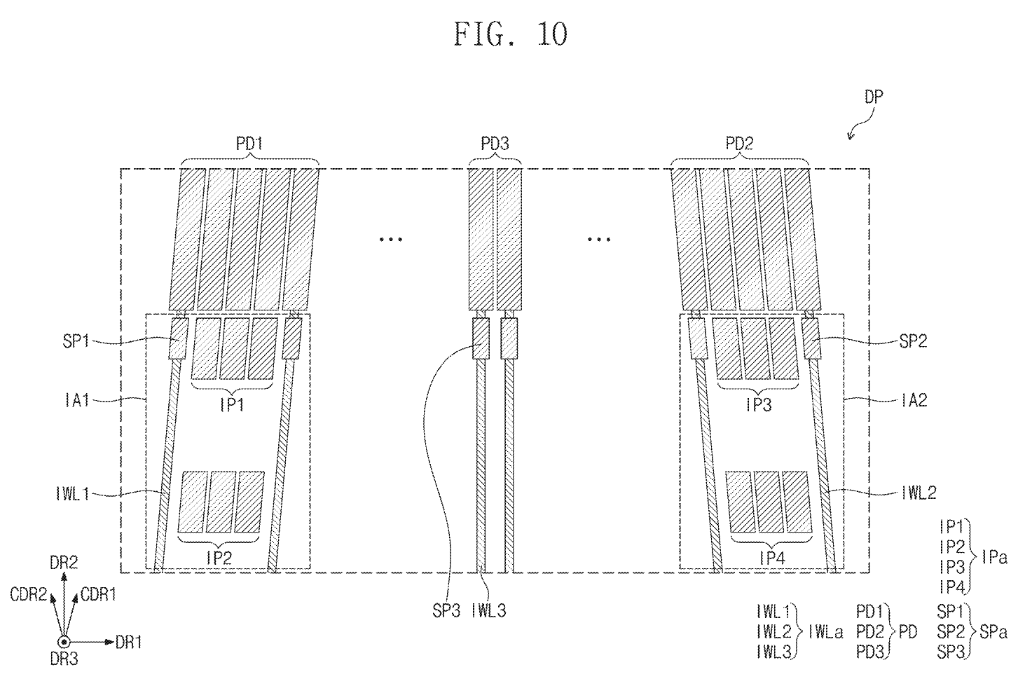

FIG. 10 is a view illustrating a portion of a display panel DP according to an embodiment of the inventive concept.

Referring to FIG. 10, pads PD according to an embodiment of the inventive concept may include first pads PD1, second pads PD2, and third pads PD3. The first pads PD1 and the second pads PD2 may be spaced apart from each other in the first direction DR1 on the basis of the third pads PD3. The first pads PD1 may extend in the first diagonal direction CDR1, the second pads PD2 may extend in the second diagonal direction CDR2, and the third pads PD3 may extend in the second direction DR2.

The direction in which the first pads PD1 extend, i.e., the first diagonal direction CDR1, is a direction inclined at a first angle clockwise with respect to the second direction DR2. The direction in which the second pads PD2 extend, i.e., the second diagonal direction CDR2, is a direction inclined at the first angle counterclockwise with respect to the second direction DR2. The first angle may gradually decrease as the first pads PD1 and the second pads PD2 are closer to the third pads PD3.

Inspection areas IA1 and IA2 may be respectively defined at the outermost portions of the pad area PA (see FIG. 4A) on a plane, specifically on opposite sides of the pad area PA in the first direction DR1. The inspection areas IA1 and IA2 may include a first inspection area IA1 disposed on the left of the pad area PA in the first direction DR1, and a second inspection area IA2 disposed on the right of the pad area PA in the first direction DR1.

An inspection pattern IPa may include first to fourth inspection patterns IP1, IP2, IP3 and IP4. The first and second inspection patterns IP1 and IP2 may be disposed in the first inspection area IA1, and the third and fourth inspection patterns IP3 and IP4 may be disposed in the second inspection area IA2.

A plurality of sub-patterns SPa may include a first sub-pattern SP1, a second sub-pattern SP2, and a third sub-pattern SP3. The first sub-pattern SP1 may be disposed in the first inspection area IA1, and the second sub-pattern SP2 may be disposed in the second inspection area IA2. The third sub-pattern SP3 may be disposed between the first sub-pattern SP1 and the second sub-pattern SP2.

An inspection line IWLa may include a first inspection line IWL1, a second inspection line IWL2, and a third inspection line IWL3. The first inspection line IWL1 may be disposed in the first inspection area IA1, and the second inspection line IWL2 may be disposed in the second inspection area IA2. The third inspection line IWL3 may be disposed between the first inspection line IWL1 and the second inspection line IWL2.

According to the embodiment of the inventive concept, the inspection pattern extending in the same direction as the pads may be defined in the inspection area, thereby providing a way for checking whether the pads are arranged and whether the pads and the connection pads are aligned with each other after the bonding process. Accordingly, the display device with the reliability may be provided.

In the above, description has been made with reference to embodiments of the inventive concept, but those skilled or of ordinary skill in the art may understand that various modifications and changes may be made to the inventive concept insofar as such modifications and changes do not depart from the spirit and technical scope of the inventive concept set forth in the claims to be described later.

Therefore, the technical scope of the inventive concept is not to be limited to the contents stated in the detailed description of the specification, but should be determined by the claims.

What is claimed is:

1. A display device comprising:
a display panel comprising a pad area;
a plurality of pads disposed in the pad area, aligned in a first direction, and each extending in a diagonal direction inclined at a first angle with respect to a second direction crossing the first direction; and
an inspection pattern extending in the diagonal direction and corresponding to at least a portion of the plurality of pads.

2. The display device of claim 1, wherein:
the pad area comprises an inspection area disposed at an outermost portion of the pad area in the first direction, and
the inspection pattern is disposed in the inspection area.

3. The display device of claim 2, further comprising a plurality of inspection lines electrically connected to the plurality of pads.

4. The display device of claim 3, wherein first inspection lines of the plurality of inspection lines are disposed in the inspection area and extend in the diagonal direction.

5. The display device of claim 3, wherein second inspection lines of the plurality of inspection lines are not disposed in the inspection area and extend in the second direction.

6. The display device of claim 3, wherein the plurality of inspection lines are disposed at a different layer compared to the plurality of pads.

7. The display device of claim 1, further comprising a plurality of sub-patterns electrically connected to the plurality of pads, extending in the diagonal direction, and corresponding to the plurality of pads,
wherein the plurality of pads and the plurality of sub-patterns are disposed at the same layer.

8. The display device of claim 7, further comprising connection lines which electrically connect the plurality of pads and the plurality of sub-patterns to each other.

9. The display device of claim 8, wherein:
the connection lines are disposed at a different layer compared to each of the plurality of pads and the plurality of sub-patterns,
the connection lines are electrically connected to the plurality of pads through first contact holes, and
the connection lines are electrically connected to the plurality of sub-patterns through second contact holes.

10. The display device of claim 7, further comprising an insulating layer disposed on the plurality of pads and the plurality of sub-patterns,
wherein the plurality of pads are exposed by an opening portion defined in the insulating layer.

11. The display device of claim 1, wherein the first angle gradually decreases toward a center of the pad area.

12. A display device comprising:
a display panel comprising a pad area;
a plurality of pads disposed in the pad area, aligned in a first direction, and each extending in a diagonal direction inclined at a first angle with respect to a second direction crossing the first direction;
a plurality of sub-patterns electrically connected to the plurality of pads, extending in the diagonal direction and corresponding to the plurality of pads; and
an insulating layer disposed on the plurality of pads and the plurality of sub-patterns,
wherein the plurality of pads are exposed by an opening portion defined in the insulating layer.

13. The display device of claim 12, wherein:
the plurality of pads and the plurality of sub-patterns are disposed at the same layer, and
the display device further comprises connection lines which electrically connect the plurality of pads and the plurality of sub-patterns to each other.

14. The display device of claim 13, wherein:
the connection lines are disposed at a different layer compared to each of the plurality of pads and the plurality of sub-patterns,
the connection lines are electrically connected to the plurality of pads through a first contact hole, and
the connection lines are electrically connected to the plurality of sub-patterns through a second contact hole.

15. The display device of claim 12, further comprising an inspection pattern extending in the diagonal direction and corresponding to at least a portion of the plurality of pads.

16. The display device of claim 15, wherein:
the pad area comprises an inspection area disposed at an outermost portion of the pad area in the first direction, and
the inspection pattern is disposed in the inspection area.

17. An electronic device comprising:
a display panel comprising a pad area;
a plurality of pads disposed in the pad area, aligned in a first direction, and each extending in a diagonal direction inclined at a first angle with respect to a second direction crossing the first direction;
an inspection pattern extending in the diagonal direction and corresponding to at least a portion of the plurality of pads; and
a printed circuit board comprising a plurality of connection pads and electrically connected to the display panel through the plurality of connection pads.

18. The electronic device of claim 17, wherein the plurality of connection pads are aligned in the first direction and correspond to the plurality of pads and extend in the diagonal direction.

19. The electronic device of claim 17, further comprising a conductive adhesive layer which electrically connects the plurality of connection pads and the plurality of pads to each other.

20. The electronic device of claim 17, wherein the printed circuit board comprises:
a main circuit board comprising a plurality of substrate pads arranged along the first direction;
a connection circuit board electrically connected to the display panel on one side of the connection circuit board and electrically connected to the main circuit board on another side of the connection circuit board; and
a driving chip mounted on the connection circuit board.
